(19) United States
(12) Patent Application Publication
(10) Pub. No.: US 2008/0277686 A1
(43) Pub. Date: Nov. 13, 2008

(54) Light emitting device and method for making the same

(75) Inventor: Tzong-Liang Tsai, Taichung (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Huga Optotech Inc., Taichung (TW)

(21) Appl. No.: 11/801,201

(22) Filed: May 8, 2007

(51) Int. Cl. H01L 33/00

(52) U.S. Cl. 257/103; 438/41; 257/E33.006

(57) ABSTRACT

A light emitting diode includes: an epitaxial substrate having a roughened side and formed with alternately disposed ridges and valleys at the roughened side, each of the ridges having a roughened surface that is formed with a dense concentration of alternately disposed pits and protrusions; and an epitaxial layered structure formed on and covering the ridges and the valleys of the epitaxial substrate. A method for making the light emitting diode involves forming the epitaxial substrate with the ridges and valleys prior to the formation of the epitaxial layered structure.

### BACKGROUND OF THE INVENTION

1. Field of the Invention

This invention relates to a light emitting diode, more particularly to a light emitting diode and a method involving forming an epitaxial layered structure on a roughened epitaxial substrate for making the light emitting diode.

2. Description of the Related Art

It is known in the art that the internal quantum efficiency of a light emitting diode is considerably decreased due to the presence of threading dislocation in an epitaxial crystal layer of the light emitting diode. Threading dislocation is generated when one material is formed on another material, and the larger the lattice mismatch between the two materials, the higher will be the threading dislocation density in said one material.

Referring to FIG. 1, conventional methods for reducing the threading dislocation density in an epitaxial layer 12 of a light emitting diode normally involve formation of recesses 111 in an epitaxial substrate 11, such as a sapphire substrate, prior to forming the epitaxial layer 12 on the epitaxial substrate 11. In these conventional methods, formation of the recesses 111 is usually conducted by wet or dry etching techniques. During dry or wet etching, the epitaxial substrate 11 is covered with a patterned mask so as to define a plurality of exposed regions for etching, followed by etching at the exposed regions so as to form the recesses 111. However, since only local surfaces of the recessed regions of the epitaxial substrate 11 are roughened as a result of the etching, and since the surface 112 of the remaining region of the epitaxial substrate 11, which is covered by the mask, is not roughened and remains flat, reduction of the threading dislocation is limited. Moreover, for the case of wet etching, the local surfaces of the recessed regions thus formed normally have a relatively low roughness, which can hardly provide further enhancement in the reduction of the threading dislocation density. Examples of forming the recesses in the epitaxial substrate can be seen in U.S. Pat. Nos. 6,936,851 and 7,033,854.

In addition, U.S. Pat. No. 6,504,183 discloses a method involving forming multiple nucleuses on an epitaxial substrate, forming a dislocation inhibition layer on the multiple nucleuses and the epitaxial substrate, followed by forming an epitaxial layer on the dislocation inhibition layer. With the inclusion of the multiple nucleuses, the dislocation inhibition layer is able to be formed with a plurality of alternately disposed protrusions and recesses, which can provide an effect in reducing the formation of the threading dislocation in the epitaxial layer. However, the local surfaces of the protrusions and the recessed regions thus formed still have a relatively low roughness and remain substantially flat, and thus cannot provide further enhancement in the reduction of the threading dislocation density.

### SUMMARY OF THE INVENTION

The object of the present invention is to provide a light emitting diode including a roughened epitaxial substrate having roughened ridges that permit an epitaxial layer formed on the epitaxial substrate to exhibit a relatively low threading dislocation density.

Another object of the present invention is to provide a method for making the light emitting diode that can overcome the aforesaid drawbacks associated with the prior art.

According to one aspect of this invention, there is provided a light emitting diode that comprises: an epitaxial substrate having a roughened side and formed with alternately disposed ridges and valleys at the roughened side, each of the ridges having a roughened surface that is formed with a dense concentration of alternately disposed pits and protrusions; and an epitaxial layered structure formed on and covering the ridges and the valleys of the epitaxial substrate.

According to another aspect of this invention, there is provided a method for making a light emitting diode that comprises: (a) forming a mask layer on an epitaxial substrate; (b) roughening the mask layer so as to form the mask layer with alternately disposed mask ridges and mask valleys; (c) anisotropically etching the roughened mask layer and the underlying epitaxial substrate in such a manner to remove the entire roughened mask layer from the epitaxial substrate and to roughen the epitaxial substrate so as to form the epitaxial substrate with alternately disposed substrate ridges and substrate valleys, which correspond respectively to the mask ridges and the mask valleys, such that each of the substrate ridges has a roughened surface that is formed with a dense concentration of alternately disposed pits and protrusions; and (d) forming an epitaxial layered structure on the substrate ridges and the substrate valleys of the epitaxial substrate.

According to yet another aspect of this invention, there is provided a method for making a light emitting diode that comprises: (a) roughening an epitaxial substrate through techniques selected from the group consisting of sandblasting techniques and mechanical polishing techniques so as to form the epitaxial substrate with alternately disposed ridges and valleys such that each of the ridges has a roughened surface that is formed with a dense concentration of alternately disposed pits and protrusions; and (b) forming an epitaxial layered structure on the ridges and the valleys of the epitaxial substrate.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is a fragmentary schematic view illustrating the configuration of an epitaxial substrate of a conventional light emitting diode;

FIG. 2 is a fragmentary schematic view of the preferred embodiment of a light emitting diode according to this invention;

FIG. 3 is an enlarged view to illustrate the configuration of a roughened epitaxial substrate of the preferred embodiment;

FIGS. 4A to 4D are schematic views to illustrate consecutive steps of the first preferred embodiment of a method for making the light emitting diode according to this invention;

FIGS. 5A to 5C are schematic views to illustrate consecutive steps of the second preferred embodiment of the method for making the light emitting diode according to this invention; and

FIG. 6 is an atomic force microscopic view of a roughened surface of the epitaxial substrate of the light emitting diode formed by the first preferred embodiment.

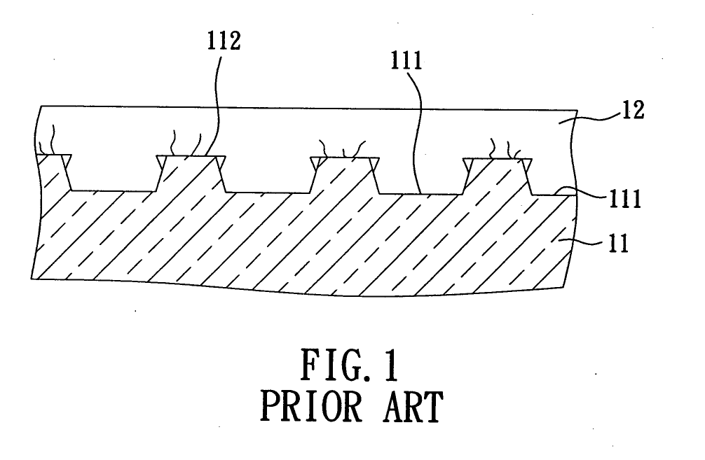

### DETAILED DESCRIPTION OF THE PREFERRED EMBODIMENTS

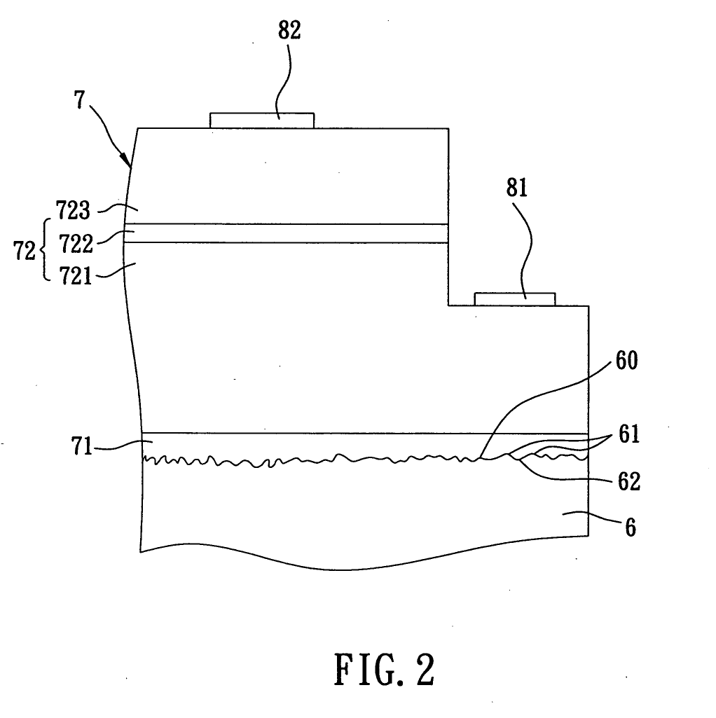

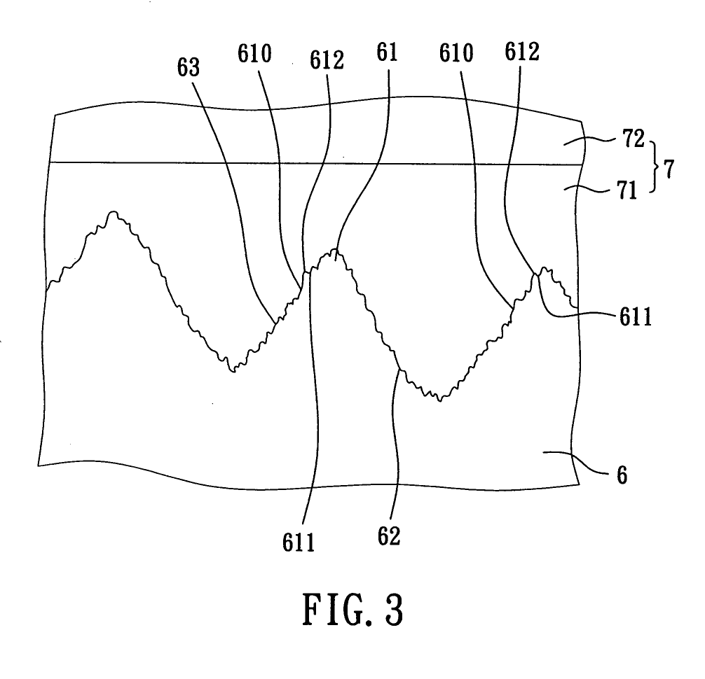

FIGS. 2 and 3 illustrate the preferred embodiment of a light emitting diode according to this invention. The light emitting diode includes: an epitaxial substrate 6 having a roughened side 60 and formed with alternately disposed ridges 61 and valleys 62 at the roughened side 60, each of the ridges 61 having a roughened surface 610 that is formed with a dense concentration of alternately disposed pits 611 and protrusions 612; and an epitaxial layered structure 7 formed on and covering the ridges 61 and the valleys 62 of the epitaxial substrate 6.

Each of the ridges 61 has a ridgeline 63. The pits 611 and the protrusions 612, which lie on the ridgeline 63 of each of the ridges 61, form the ridgeline 63 of the respective one of the ridges 61 into a generally teeth-like tortuous profile. Each of the valleys 62 is surrounded and defined by adjacent ones of the ridges 61, and is in spatial communication with adjacent ones of the valleys 62.

The epitaxial substrate 6 is preferably made from a material selected from the group consisting of sapphire, SiC, Si, ZnO, GaAs, GaN, and MgAl₂O₄ having a spinel structure. In this embodiment, the expitaxial substrate 6 is made from sapphire. Preferably, the roughened side 60 of the epitaxial substrate 6 has an average roughness (Ra) ranging from 0.5 nm to 1000 nm, and more preferably ranging from 0.5 nm to 500 nm.

The epitaxial layered structure 7 includes a nuclide layer 71 that is formed on the ridges 61 and the valleys 62 of the epitaxial substrate 6, and an epitaxial layer 72 that is formed on the nuclide layer 71. The epitaxial layer 72 is made from a III-V compound. The III group element is selected from the group consisting of B, Al, Ga, In, Ti, and combinations thereof, and the V group element is selected from the group consisting of N, P, As, Sb, Bi, and combinations thereof.

The epitaxial layer 72 includes first and second semiconductor layers 721, 723 and an active layer 722 sandwiched between the first and second semiconductor layers 721, 723. The first semiconductor layer 721 is formed on the nuclide layer 71. First and second electrode contacts 81, 82 are formed on the first and second semiconductor layers 721, 723, respectively.

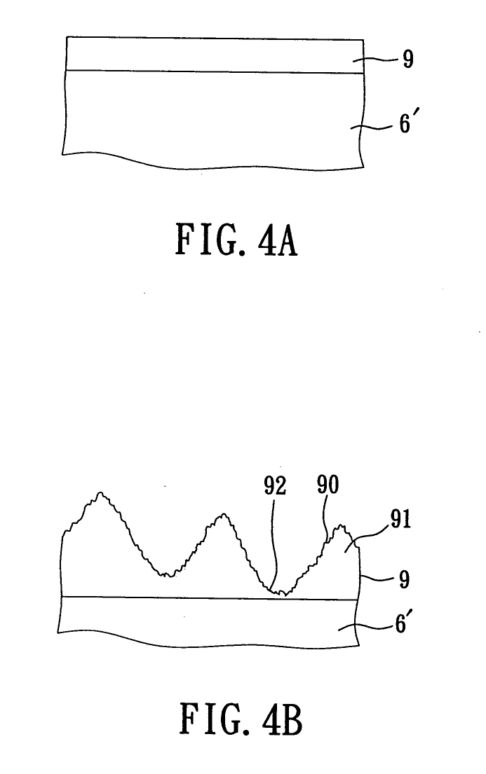

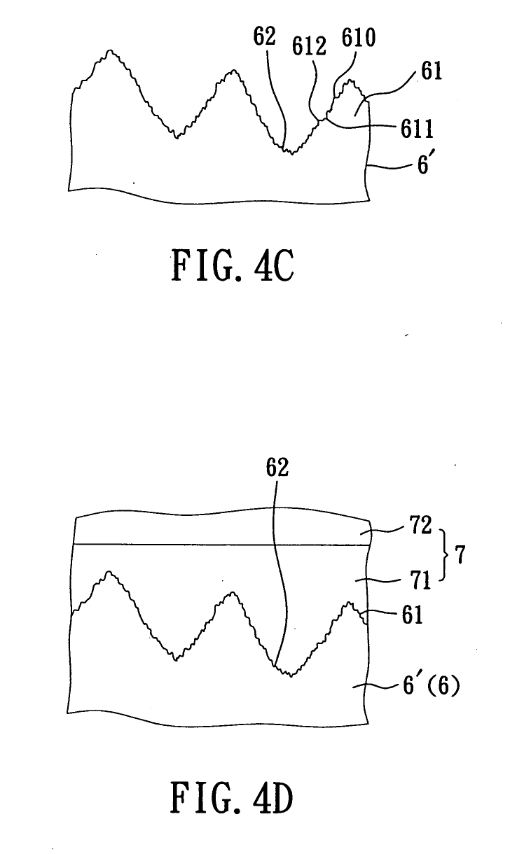

FIGS. 4A to 4D illustrate consecutive steps of the first preferred embodiment of a method for making the light emitting diode according to this invention. The method includes: (a) forming a mask layer 9 on an epitaxial substrate 6′ (see FIG. 4A); (b) roughening the mask layer 9 (see FIG. 4B) so as to form the mask layer 9 with alternately disposed mask ridges 91 and mask valleys 92 such that each of the ridges 91 or each of the valleys 92 has a roughened surface 90 with a generally teeth-like profile; (c) anisotropically etching the roughened mask layer 9 and the underlying epitaxial substrate 6′ in such a manner to remove the entire roughened mask layer 9 from the epitaxial substrate 6′ and to roughen the epitaxial substrate 6′ so as to form the epitaxial substrate 6′ with the alternately disposed substrate ridges 61 and substrate valleys 62, which correspond respectively to the mask ridges 91 and the mask valleys 92, such that each of the substrate ridges 61 or each of the substrate valleys 62 has the roughened surface 610 that is formed with a dense concentration of the alternately disposed pits 611 and protrusions 612 (see FIG. 4C); and (d) forming the epitaxial layered structure 7 on the substrate ridges 61 and the substrate valleys 62 of the roughened epitaxial substrate 6 (see FIG. 4D).

Roughening of the mask layer 9 instep (b) is conducted by techniques selected from the group consisting of annealing techniques, wet etching techniques, mechanical polishing techniques, and sandblasting techniques. In annealing techniques, the annealed material may exhibit a compressive stress or a tensile stress. In one preferred embodiment, the annealed mask layer 9 exhibits a compressive stress.

When roughening is conducted by annealing techniques, the mask layer 9 is preferably made from a material selected from the group consisting of a photoresist material and a metallic material. The metallic material is selected from the group consisting of Ni, Ag, Al, Au, Pt, Pd, Zn, Cd, Cu, and combinations thereof. The photoresist material is selected from the group consisting of SU-8®, benzocyclobutene (BCB), polyimide, EPG-516®, AZ-5214®, and DNR-L300-D1®. Alternatively, the mask layer 9 can be a combination of a base film, such as a SiO₂ film, and a photoresist film, such as an EPG-516® film. In one preferred embodiment, the mask layer 9 is made from Ni, and has a layer thickness ranging from 50 nm to 2000 nm. When the layer thickness of the mask layer 9 is too large, the effect of compressive stress acting on the annealed mask layer 9 is poor. When the layer thickness of the mask layer 9 is too small, the desired roughness of the roughened surface 90 of the mask layer 9 cannot be achieved. In one preferred embodiment, roughening of the mask layer 9 in step (b) is preferably conducted at an annealing temperature ranging from 400° C. to 1000° C., more preferably ranging from 500° C. to 800° C., and most preferably ranging from 600° C. to 750° C. When the annealing temperature is too high, the mask layer 9 will deteriorate. When the annealing temperature is too low, the desired roughness of the roughened surface 90 of the mask layer 9 cannot be achieved.

When roughening is conducted by sandblasting techniques, the mask layer 9 formed in step (a) is preferably made from a metallic material selected from the group consisting of Ni, Cu, Ti, Au, and Pt, and has a layer thickness ranging from 50 nm to 5000 nm. In one preferred embodiment, roughening of the mask layer 9 in step (b) is conducted using sandblast beads selected from the group consisting of Al₂O₃ beads, SiC beads, black alumina beads, steel shots, bronze alloy shots, ceramic beads, alumina beads, stainless shots, plastic beads, walnut powder, SiO₂ beads, B₄C beads, and combinations thereof. The sandblast beads used in step (b) preferably have a particle diameter ranging from 0.05 μm to 500 μm. Sandblasting of the mask layer 9 in step (b) is conducted using a sandblasting apparatus (not shown) with a nozzle which is disposed in such a manner that the distance between the mask layer 9 and a bead outlet of the nozzle ranges from 20 cm to 30 cm. In this preferred embodiment, the sandblasting apparatus is operated under a working pressure 0.005 kg/cm² to 10 kg/cm² during sandblasting of the mask layer 9.

Preferably, the roughened surface 90 of the roughened mask layer 9 formed in step (b) has an average roughness ranging from 0.5 nm to 1000 nm, and more preferably, ranging from 0.5 nm to 500 nm. When the roughness of the roughened surface 90 of the mask layer 9 is too large, formation of the epitaxial layered structure 7 on the epitaxial substrate 6 is likely to fail. When the roughness of the roughened surface 90 of the mask layer 9 is too small, reduction of the threading dislocation density in the epitaxial layered structure 7 is poor.

After forming the mask layer 9 with the mask ridges 91 and the mask valleys 92 with a predetermined profile, the subsequent anisotropically etching (in this embodiment, dry etching is used) is conducted so as to form the epitaxial substrate 6 with the substrate ridges 61 and substrate valleys 62 having a desired profile.

Preferably, formation of the nuclide layer 71 is conducted at a working temperature ranging from 450° C. to 1000° C., and formation of the epitaxial layer 72 is conducted at a working temperature ranging from 650° C. to 1300° C.

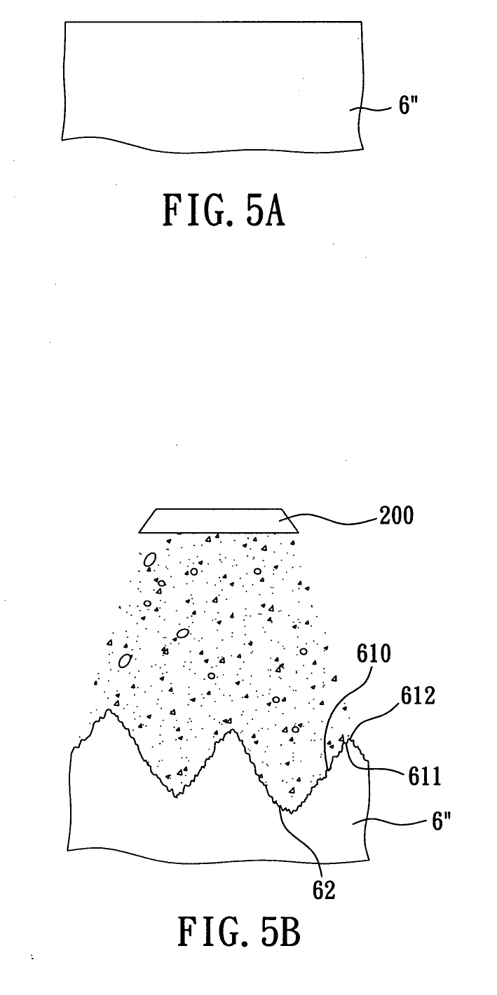

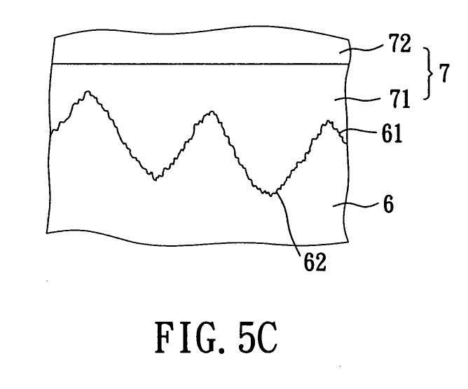

FIGS. 5A to 5C illustrate consecutive steps of the second preferred embodiment of the method for making the light emitting diode according to this invention. The method includes: (a) roughening an epitaxial substrate 6″ through sandblasting techniques (see FIGS. 5A and 5B) so as to form the epitaxial substrate 6″ with alternately disposed ridges 61 and valleys 62 such that each of the ridges 61 or each of the valleys 62 has the roughened surface 610 that is formed with a dense concentration of the alternately disposed pits 611 and protrusions 612; and (b) forming the epitaxial layered structure 7 on the ridges 61 and the valleys 62 of the epitaxial substrate 6 (see FIG. 5C). Alternatively, roughening of the epitaxial substrate 6″ can be conducted through mechanical polishing techniques. The nozzle 200 (see FIG. 5B) of the sandblasting apparatus used in this preferred embodiment is disposed in such a manner that the distance between the epitaxial substrate 6″ and the bead outlet of the nozzle 200 preferably ranges from 15 cm to 30 cm. The sandblasting apparatus is preferably operated under a working pressure ranging from 0.05 kg/cm² to 50 kg/cm² during sandblasting of the epitaxial substrate 6″. In this preferred embodiment, the sandblast beads preferably have a particle diameter ranging from 1 μm to 500 μm.

Note that in the first preferred embodiment, the epitaxial substrate 6′ is roughened by dry etching techniques with the requirements of pre-forming and pre-roughening the mask layer 9, while, in the second preferred embodiment, the epitaxial substrate 6″ is directly roughened by sandblasting or mechanical polishing techniques without pre-forming the mask layer 9 achieve the desired roughness for the roughened side 60 of the epitaxial layer 6 and the desired teeth-like tortuous profile for the ridgeline 63 of each ridge 61 or valley 62.

The merits of the method of making the light emitting diode of this invention will become apparent with reference to the following Examples.

### EXAMPLE 1

The light emitting diode of Example 1 was prepared by the following steps.

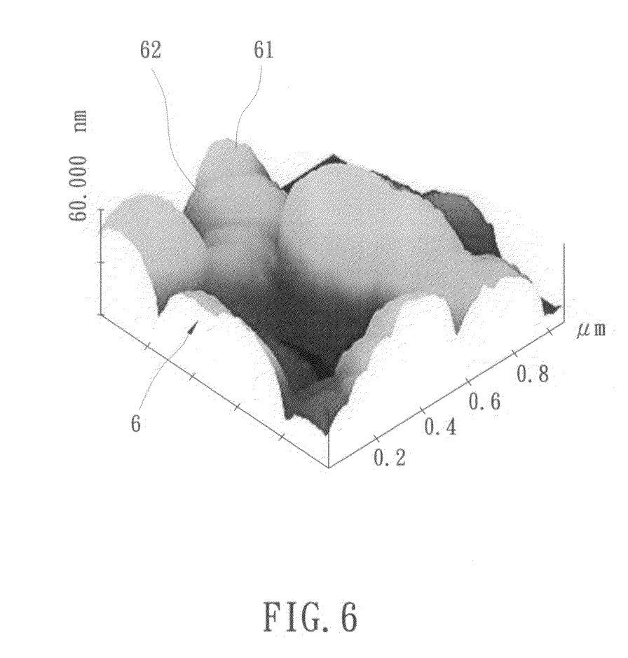

A Ni film serving as the mask layer 9 and having a layer thickness of 30 nm was formed on a sapphire substrate 6 using e-beam evaporation techniques at a working temperature of 600° C. The Ni film thus formed was subjected to annealing treatment at an annealing temperature of 600° C. for 10 minutes for permitting atomic migration which led to roughening of the Ni film. The layered structure was then subjected to reactive ion etching (RIE) for removing the Ni film and roughening the sapphire substrate 6. FIG. 6 is an atomic force microscopic (AFM) graph showing a roughened surface of the roughened sapphire substrate 6 with the ridges 61 and valleys 62. The roughness (Ra) of the roughened surface of the sapphire substrate 6 was measured, and was about 10 nm. The roughened sapphire substrate 6 was then placed into a MOCVD system into which a reactant mixture of (CH₃)₃Ga (TMG):NH3 (gas flow rate ratio=1:500) was introduced for reaction under a working temperature of 540° C. and a working pressure of 500 mTorr for forming a GaN nuclide layer 71 on the roughened sapphire substrate 6. After formation of the GaN nuclide layer 71, a reactant mixture of (CH₃)₃Ga (TMG):NH3 (gas flow rate ratio=1:2500) was subsequently introduced into the MOCVD system for reaction under a working temperature of 1050° C. and a working pressure of 200 mTorr for forming a GaN-based epitaxial layer 72. The layered structure thus formed was then formed with the first and second electrode contacts 81, 82.

### EXAMPLE 2

The light emitting diode of Example 2 was prepared by steps similar to those of Example 1, except that the Ni film formed on the sapphire substrate 6 had a layer thickness of 500 nm, and that the Ni film was removed and the sapphire substrate 6 was roughened using sandblasting techniques under a working pressure of 100 g/cm² for 5 seconds. SiO₂ beads having particle diameters 20 μm, 10 μm, and 5 μm in a ratio of 1:1:1 were used, and the distance between the bead outlet of the nozzle and the Ni film was set at 20 cm. The roughness (Ra) of the roughened surface of the sapphire substrate 6 was measured, and was about 10 nm.

### EXAMPLE 3

The light emitting diode of Example 3 was prepared by steps similar to those of Example 1, except that the Ni film was dispensed with for this Example, and that the sapphire substrate 6 was directly roughened using sandblasting techniques under a working pressure of 2 Kg/cm² for 60 seconds. SiO₂ beads having particle diameters 50 μm, 20 μm, and 10 μm in a ratio of 1:1:1 were used, and the distance between the bead outlet of the nozzle 200 and the Ni film was set at 15 cm. The roughness (Ra) of the roughened surface of the sapphire substrate 6 was measured, and was about 15 nm.

By forming the epitaxial substrate 6 with the ridges 61 and valleys 62, and by roughening each ridge 61 or each valley 62 with a teeth-like profiled ridgeline according to the method of the present invention, the aforesaid drawbacks associated with the prior art can be eliminated.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A light emitting diode comprising:
an epitaxial substrate having a roughened side and formed with alternately disposed ridges and valleys at said roughened side, each of said ridges having a roughened surface that is formed with a dense concentration of alternately disposed pits and protrusions; and
an epitaxial layered structure formed on and covering said ridges and said valleys of said epitaxial substrate.

2. The light emitting diode of claim 1, wherein each of said ridges has a ridgeline, said pits and said protrusions, which lie on said ridgeline of each of said ridges, forming said ridgeline of the respective one of said ridges into a tortuous profile.

3. The light emitting diode of claim 1, wherein each of said valleys is surrounded and defined by adjacent ones of said ridges, and is in spatial communication with adjacent ones of said valleys.

4. The light emitting diode of claim 1, wherein said epitaxial substrate is made from a material selected from the group consisting of sapphire, SiC, Si, ZnO, GaAs, GaN, and MgAl₂O₄ having a spinel structure.

5. The light emitting diode of claim 1, wherein said roughened side of said epitaxial substrate has an average roughness ranging from 0.5 nm to 1000 nm.

6. The light emitting diode of claim 5, wherein said average roughness of said roughened side of said epitaxial substrate ranges from 0.5 nm to 500 nm.

7. The light emitting diode of claim 1, wherein said epitaxial layered structure includes a nuclide layer that is formed on said ridges and said valleys of said epitaxial substrate, and an epitaxial layer that is formed on said nuclide layer.

8. The light emitting diode of claim 7, wherein said epitaxial layer is made from a III-V compound, said III group element being selected from the group consisting of B, Al, Ga, In, Ti, and combinations thereof, said V group element being selected from the group consisting of N, P, As, Sb, Bi, and combinations thereof.

9. The light emitting diode of claim 7, wherein said epitaxial layer includes first and second semiconductor layers and an active layer sandwiched between said first and second semiconductor layers, said first semiconductor layer being formed on said nuclide layer.

10. The light emitting diode of claim 9, further comprising first and second electrode contacts formed on said first and second semiconductor layers, respectively.

11. A method for making a light emitting diode, comprising:
(a) forming a mask layer on an epitaxial substrate;
(b) roughening the mask layer so as to form the mask layer with alternately disposed mask ridges and mask valleys;
(c) anisotropically etching the roughened mask layer and the underlying epitaxial substrate in such a manner to remove the entire roughened mask layer from the epitaxial substrate and to roughen the epitaxial substrate so as to form the epitaxial substrate with alternately disposed substrate ridges and substrate valleys, which correspond respectively to the mask ridges and the mask valleys, such that each of the substrate ridges has a roughened surface that is formed with a dense concentration of alternately disposed pits and protrusions; and
(d) forming an epitaxial layered structure on the substrate ridges and the substrate valleys of the epitaxial substrate.

12. The method of claim 11, wherein roughening of the mask layer in step (b) is conducted by techniques selected from the group consisting of annealing techniques, wet etching techniques, mechanical polishing techniques, and sandblasting techniques.

13. The method of claim 12, wherein roughening of the mask layer in step (b) is conducted by annealing techniques.

14. The method of claim 13, wherein the mask layer is made from a material selected from the group consisting of a photoresist material and a metallic material.

15. The method of claim 14, wherein the metallic material is selected from the group consisting of Ni, Ag, Al, Au, Pt, Pd, Zn, Cd, Cu, and combinations thereof.

16. The method of claim 15, wherein the metallic material is Ni.

17. The method of claim 16, wherein the mask layer formed in step (a) has a layer thickness ranging from 50 nm to 2000 nm.

18. The method of claim 16, wherein roughening of the mask layer in step (b) is conducted at an annealing temperature ranging from 400° C. to 1000° C.

19. The method of claim 12, wherein roughening of the mask layer in step (b) is conducted by sandblasting techniques, and the mask layer is made from a metallic material.

20. The method of claim 19, wherein the mask layer formed in step (a) has a layer thickness ranging from 50 nm to 5000 nm.

21. The method of claim 20, wherein roughening of the mask layer in step (b) is conducted using sandblast beads selected from the group consisting of Al₂O₃ beads, SiC beads, black alumina beads, steel shots, bronze alloy shots, ceramic beads, alumina beads, stainless shots, plastic beads, walnut powder, SiO₂ beads, B₄C beads, and combinations thereof.

22. The method of claim 21, wherein the sandblast beads used in step (b) have a particle diameter ranging from 0.05 μm to 500 μm.

23. The method of claim 19, wherein sandblasting of the mask layer in step (b) is conducted using a sandblasting apparatus with a nozzle which is disposed in such a manner that the distance between the mask layer and a bead outlet of the nozzle ranges from 20 cm to 30 cm.

24. The method of claim 23, wherein the sandblasting apparatus is operated under a working pressure 0.005 kg/cm² to 10 kg/cm² during sandblasting of the mask layer.

25. The method of claim 11, wherein the roughened mask layer formed in step (b) has a roughened surface with an average roughness ranging from 0.5 nm to 1000 nm.

26. The method of claim 25, wherein the average roughness of the roughened surface of the roughened mask layer ranges from 0.5 nm to 500 nm.

27. The method of claim 11, wherein the epitaxial layered structure formed in step (d) includes a nuclide layer and an epitaxial layer, the nuclide layer being formed on the etched epitaxial substrate formed after step (c).

28. The method of claim 27, wherein formation of the nuclide layer is conducted at a working temperature ranging from 450° C. to 1000° C., and formation of the epitaxial layer is conducted at a working temperature ranging from 650° C. to 1300° C.

29. The method of claim 27, wherein the epitaxial layer is made from a III-V compound, the III group element being selected from the group consisting of B, Al, Ga, In, Ti, and combinations thereof, the V group element being selected from the group consisting of N, P, As, Sb, Bi, and combinations thereof.

30. The method of claim 29, wherein the epitaxial layer includes first and second semiconductor layers and an active layer sandwiched between the first and second semiconductor layers, the first semiconductor layer being formed on said nuclide layer.

31. The method of claim 30, further comprising forming first and second electrode contacts on the first and second semiconductor layers, respectively.

32. The method of claim 11, wherein the epitaxial substrate is made from a material selected from the group consisting of sapphire, SiC, Si, ZnO, GaAs, GaN, and MgAl₂O₄ having a spinel structure.

33. A method for making a light emitting diode, comprising:
(a) roughening an epitaxial substrate through techniques selected from the group consisting of sandblasting techniques and mechanical polishing techniques so as to form the epitaxial substrate with alternately disposed ridges and valleys such that each of the ridges has a roughened surface that is formed with a dense concentration of alternately disposed pits and protrusions; and
(b) forming an epitaxial layered structure on the ridges and the valleys of the epitaxial substrate.

34. The method of claim 33, wherein roughening of the epitaxial substrate in step (a) is conducted using sandblasting techniques.

35. The method of claim 34, wherein roughening of the epitaxial substrate in step (a) is conducted using sandblast beads selected from the group consisting of Al₂O₃ beads, SiC beads, black alumina beads, steel shots, bronze alloy shots, ceramic beads, alumina beads, stainless shots, plastic beads, walnut powder, SiO₂ beads, B₄C beads, and combinations thereof.

36. The method of claim 35, wherein the sandblast beads have a particle diameter ranging from 1 μm to 500 μm.

37. The method of claim 35, wherein sandblasting of the epitaxial substrate is conducted using a sandblasting apparatus with a nozzle which is disposed in such a manner that the distance between the epitaxial substrate and a bead outlet of the nozzle ranges from 15 cm to 30 cm.

38. The method of claim 37, wherein the sandblasting apparatus is operated under a working pressure ranging from 0.05 kg/cm² to 50 kg/cm² during sandblasting of the epitaxial substrate.

39. The method of claim 33, wherein the roughened epitaxial substrate formed in step (a) has a roughened side formed with the ridges and the valleys and having an average roughness ranging from 0.5 nm to 1000 nm.

40. The method of claim 39, wherein the average roughness of the roughened side of the epitaxial substrate ranges from 0.5 nm to 500 nm.

41. The method of claim 33, wherein the epitaxial layered structure formed in step (b) includes a nuclide layer and an epitaxial layer, the nuclide layer being formed on the roughened epitaxial substrate after step (a).

42. The method of claim 41, where information of the nuclide layer is conducted at a working temperature ranging from 450° C. to 1000° C., and formation of the epitaxial layer is conducted at a working temperature ranging from 650° C. to 1300° C.

43. The method of claim 41, wherein the epitaxial layer is made from a III-V compound, the III group element being selected from the group consisting of B, Al, Ga, In, Ti, and combinations thereof, the V group element being selected from the group consisting of N, P, As, Sb, Bi, and combinations thereof.

44. The method of claim 43, wherein the epitaxial layer includes first and second semiconductor layers and an active layer sandwiched between the first and second semiconductor layers, the first semiconductor layer being formed on said nuclide layer.

45. The method of claim 44, further comprising forming first and second electrode contacts on the first and second semiconductor layers, respectively.
